(19) United States
(12) Patent Application Publication
(10) Pub. No.: US 2005/0281199 A1
(43) Pub. Date: Dec. 22, 2005

(54) Method and system for communications routing

(76) Inventors: Grant M.F. Simpson, Phoenix, AZ (US); Scott L. Schaeferle, Anthem, AZ (US)

Correspondence Address: ETHERTON LAW GROUP, LLC, 5555 E. VAN BUREN STREET, SUITE 100, PHOENIX, AZ, 85008, US

(21) Appl. No.: 11/159,556

(22) Filed: Jun. 22, 2005

Related U.S. Application Data
(60) Provisional application No. 60/582,303, filed on Jun. 22, 2004.

(51) Int. Cl. G01R 31/08; G06F 11/00

(52) U.S. Cl. 370/238

(57) ABSTRACT

A method and system for communications routing provides an improved range of service quality and cost options. The method includes receiving at a host computer system an indication that a user has placed a telephone call. Next the host computer system receives from a routing database operatively connected to the host computer system both QoS criteria and cost criteria. The QoS criteria and cost criteria are then matched with empirical QoS data and least-cost routing data, respectively. A call route is then determined based on the matched QoS criteria and cost criteria with empirical QoS data and least-cost routing data, respectively. The routing database is then updated based on whether the determined call route provided an acceptable QoS.

### FIELD OF THE INVENTION

The present invention relates generally to communications routing procedures, and more particularly to optimized telephone call routing using least-cost statistics and empirical, real-time quality of service data. This application claims the benefit of co-pending U.S. Provisional Application No. 60/582,303 filed Jun. 22, 2004.

### BACKGROUND OF THE INVENTION

Telephone service is a worldwide, multi-billion dollar business. Vast numbers of telephone calls are made simultaneously and routed through points of nexus, such as telephone companies, call centers, and even companies that handle pre-paid calling cards. It is well known in the prior art for call-handling businesses to choose a communication path based on the concept of least-cost routing.

Take, for example, the pre-paid calling industry. Prepaid calling cards are typically printed in standard denominations such as $10 or $25 and are purchased by consumers at grocery stores or convenience stores. The cards usually include a toll-free access telephone number and a personal identification number (PIN). To use the cards, consumers first dial the access number and type in their PIN, which then connects them to a host computer. The computer then prompts the consumer for the telephone number that the consumer wants to call, often including a country code and area code. The host computer then accesses a routing database to determine a path for routing the call, and finally places the call through the determined path.

In modern deregulated telecommunications markets, the companies that sell calling cards typically are not telephone companies. Instead, the calling card sellers contract with carriers and other intermediaries to transmit the calls. The contract price for individual calls is determined by bulk rates negotiated between the calling card seller and a carrier. Generally, as the number of calls negotiated in a contract increases, the price per call decreases. Savings based on large contracts represent profit for the card seller, as the price per call for the consumer (the calling card price) remains constant for a given card.

It is well known in the prior art for calling card companies therefore to choose a communication path based on the concept of least-cost routing. Here, a calling card company can select a specific route for a given call based on often hundreds of options from numerous carriers. The options may include use of Plain Old Telephone Service (POTS) systems such as a Public Switched Telephone Network (PSTN) as well as systems such as cable, integrated services digital network (ISDN), digital subscriber line (DSL) and even wireless links. The routing database of the calling card company includes the negotiated rates for the various possible routing legs of a call, so the company's computer can then determine a low-cost route.

Naturally, each carrier wants to carry more calls so as to maximize revenue. Problems arise however when a given carrier has too many calls on its facilities or its facilities fail. Calls may fail to go through, get dropped, or sound quality may decrease. So, to maintain reliable and high-quality systems, calling card sellers often need to avoid pure least-cost routing methods and incorporate quality of service (QoS) factors into their routing calculations.

Prior art methods of incorporating both QoS factors and least-cost statistics into routing calculations include various strategies. For example, some prior art techniques include “auto switching,” as required, between a public switched telephone network (PSTN) and a data network, in response to real-time changes in QoS as a call is carried over a given route. These techniques however require complex, dynamic QoS monitoring procedures and equipment. The procedures take into account only current QoS data, as opposed to historical data which may provide more accurate overall information. Also, because call routes are based initially on only least-cost factors, the initial call connections are likely to suffer QoS problems that may be noticeable to a consumer.

Other prior art publications concerning combining QoS factors and least-cost statistics suggest that consumers define criteria that may include least cost, best service, or least cost available for a given quality standard. The criteria may then be applied on a per call basis or on an aggregated basis where a consumer can update their criteria periodically. For each call by a particular consumer, a processing system then matches the consumer's requested criteria with presently available service options to determine a best call route. A drawback of these systems is that the QoS factors used to determine an ideal route is drawn from calling plan and rating information provided by the carriers themselves. Similar to routing cost information stored in a calling card company's routing database, the QoS information is not updated in real time and may not use empirical data. The QoS information is generally updated on only an intermittent basis, determined by the carriers, and may or may not be accurate.

There is therefore a need for a proactive system of monitoring call results that takes actions to give a higher-quality call, and gives customers enhanced service in real time based on then-current conditions without manual intervention. It would also be desirable for the call-handler to offer different levels of service based on the individual customer. For example, it might be desirable to move a premium customer (one who is paying more) to higher cost facilities immediately when the lower cost facilities are out of spec. Conversely, a customer who is paying the lowest cost would not be moved to more expensive facilities when the lower cost facilities are out of spec. Instead, the customer would suffer lower-quality calls and might be motivated to a higher cost, premium plan.

There is therefore a need for an improved least-cost communications routing method that enables optimal communications routing using both empirical, real-time QoS factors and cost statistics, thus considering best-quality-for-least-cost.

### SUMMARY OF THE INVENTION

According to one aspect, the present invention is therefore a method for communications routing that provides an improved range of service quality and cost options. The method includes receiving at a host computer system an indication that a user has placed a telephone call. Next the host computer system receives from a routing database operatively connected to the host computer system both QoS criteria and cost criteria. The QoS criteria and cost criteria are then matched with empirical QoS data and least-cost routing data, respectively. A call route is then determined based on the matched QoS criteria and cost criteria with empirical QoS data and least-cost routing data, respectively. The routing database is then updated based on whether the determined call route provided an acceptable QoS.

According to another aspect, the present invention is a computer system that implements the above described method.

### BRIEF DESCRIPTION OF THE DRAWINGS

FIG. 1 is a flow diagram illustrating a general method of communications routing that uses both QoS factors and least-cost statistics according to an embodiment of the present invention;

FIG. 2 is a block diagram of the overview of the present invention;

FIG. 3 is a block diagram that illustrates one embodiment of a host computer system through which the present invention may be implemented; and

FIG. 4 is a flow diagram illustrating a general method for communications routing according to an embodiment of the present invention.

### DETAILED DESCRIPTION

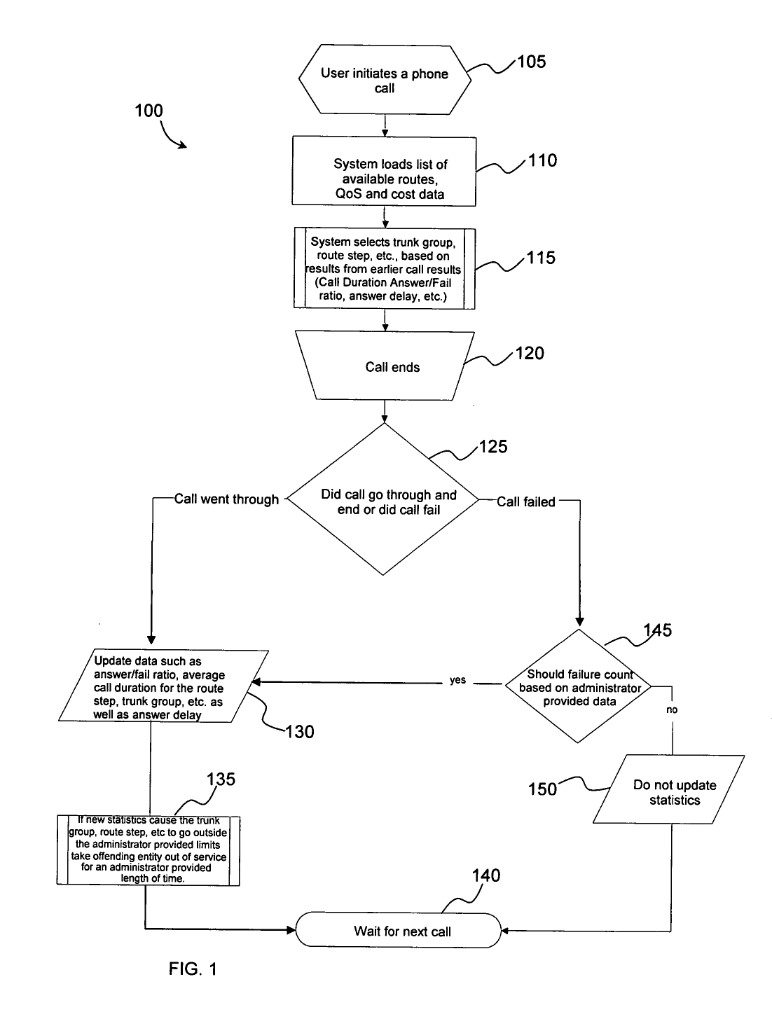

Referring to FIG. 1, there is a flow diagram illustrating a general method 100 of communications routing that uses both QoS factors and least-cost statistics according to an embodiment of the present invention. The method 100 is initiated at step 105 when a user initiates a phone call. The present invention is commonly applied to pre-paid calling systems in which the user first calls a toll-free access number located on the card and enters his or her personal identification number (PIN). When the PIN is successfully processed, the user is provided access to a host computer system 200 that prompts the user to then enter the telephone number to be called. However, while pre-paid calling cards are a common embodiment, the method may be applied to other calling systems such as those operated by call centers, telephone companies, or even businesses whose call volume is so high that they handle their own calls. Cost may be calculated on a per-call basis or for the aggregate over time, whether long distance or local.

Referring again to FIG. 1, at step 110 the system loads a list of available calling routes from a routing database as well as preferred QoS criteria and cost criteria. QoS criteria include, for example, answer/fail ratio, answer delay, decibel loss, number of retries, number of packets with errors, percentage of packets with errors, number of packets that were discarded, percentage of packets that were discarded, number of packets lost, percentage of packets lost, number of packets retransmitted, percentage of packets retransmitted, average jitter, maximum jitter, average latency, and maximum latency.

The preferred QoS criteria and cost criteria may be associated with a particular user or with a particular category of user. For example categories of users may include residential users, business users, conference call users, etc. These criteria may be interdependent and form a spectrum of QoS and cost options. For example, some users or categories of users at one end of the spectrum may require the highest quality service regardless of cost; whereas other users or categories of users at another end of the spectrum may require the absolute lowest-cost routes regardless, within reason, of service quality. Some users may require highest quality during a specific time of day which, if the desired time of day is during peak demand, may not be the lowest cost.

Continuing to step 115, the system then selects a route including a trunk group and route step by matching the loaded QoS criteria and cost criteria with the least-cost route statistics and with empirical, real-time, QoS data that is also stored in the routing database. The trunk group can be a specific port or a group of ports; the route step can refer to a specific termination point or dialed digit modification parameters. The empirical QoS data ideally includes statistics from previous calls using identical routes with identical carriers. However, if statistically meaningful data is not available for a selected route, the method of the present invention may include optimization using analogous empirical QoS data from analogous routes and carriers. The empirical QoS data may include for example call duration data, answer/fail ratio data, and answer delay data. Step 115 is completed when the optimized route based on the loaded QoS criteria, the least-cost route statistics and the empirical QoS data is planned and executed, thus connecting the call. The method 100 continues at step 120 where the call ends. A quality control sub-process for updating the empirical QoS data is now described in more detail below.

Next, at step 125, the system begins the quality control sub-process of updating the empirical QoS data using statistics from the immediately preceding call that ended at step 120. The quality control sub-process is performed in real time, meaning generally immediately within the first few seconds or minutes after a call has been completed. The system may first determine whether the call went through or whether the call failed. If the call went through, the quality control sub-process proceeds to step 130 where the routing database is updated by, for example, averaging the duration of the immediately preceding call to the overall average call duration statistics for that route step, trunk group and other particular routing leg features. The routing database is also updated by averaging the answer delay of the immediately preceding call to the overall average answer delay statistics for that route step, trunk group, and other particular routing leg features And by updating the answer/fail ratio.

By monitoring the result of each call attempt made by a phone system and recording metrics for those calls including whether or not the call went through, how long it took to go through, how long the call lasted, plus any other metric that may indicate the quality of the call, a “sample window” of data is gathered which can then be used to determine how to route future calls to a destination route (which may include a trunk or group of trunks, a voice over IP (VoIP) termination point, or any other method of carrying a call to a destination). This empirical data may be collected over a user-defined period of time. This is particularly valuable for carriers routing and switching calls using VoIP which often suffers relatively transient problems. For example, the user may define a 40 minute window for data collection, which comprises eight samples that are each five minutes long. In this way the user may define different thresholds to the sample and window to set the level of quality and relative cost for each customer or group of customers.

At step 135, the system's host computer reviews the updated statistics determined at step 130 by comparing the updated statistics with administrator provided QoS limits. The QoS limits may be set as universal limits based on advertised quality standards that are marketed by the calling card seller, or the QoS limits may include matrices of user-specific limits based on individual users' QoS criteria, as described previously. If any of the updated statistics determined at step 130 fall outside of the administrator provided QoS limits, an offending routing leg feature such as a particular carrier, or a particular trunk line, route step, or other route-specific feature that is determined to have caused the below-standard service, may be removed from an active list of route options stored in the routing database.

After a route-specific routing leg feature is removed from the active list of route options in the routing database, procedures may be incorporated into the system for adding the routing leg feature back to the active list, so as to maintain a large number of call route options for any destination selected by a user. The procedures for adding a removed routing leg feature back onto the active list of the routing database may include, for example, new QoS data provided by an offending carrier that demonstrates that a routing leg feature would now fall within the administrator provided QoS limits, or may include new empirical call data collected by the system itself during QoS route tests that do not involve actual users. The procedures for adding a removed routing leg feature back into the active list of the routing database may also include a simple suspension loop. Here, an offending routing leg feature is removed from the active list of the routing database for a predetermined suspension interval only, and is then added back to the active list at the expiration of the suspension interval. The duration of such suspension intervals may be determined by the administrator based on the average times generally required for carriers to fix various QoS problems. Finally, following step 135, the method 100 proceeds to step 140 where the system waits for the next call. When a next user dials a call, the method 100 begins again at step 105.

If however at step 125 the system determines that a call failure occurred during the immediately preceding call that ended at step 120, then the method 100 continues to step 145 where it is determined whether the call failure should count against the administrator provided QoS limits that are described above. The system may determine that a failed call should not count against the administrator provided QoS limits for various reasons. For example, in one embodiment of the present invention, the system may monitor certain transient or ephemeral external factors that may disrupt communications through a particular carrier, trunk line or route step for a particular call but that should not affect the QoS of subsequent calls. These external factors may include such problems as transient congestion in route features due to high call volume; errors such as packet loss; and metrics such as jitter. If at step 145 it is determined that the immediately preceding call failure should not count against the administrator provided QoS limits, then the method 100 continues to step 150, where the system does not update the administrator provided QoS limits. Instead the method 100 again returns to step 140 where the system waits for the next call.

If at step 145 it is determined that the immediately preceding call failure should count against the administrator provided QoS limits, then the method 100 continues to step 155 where the routing database is updated by re-averaging the call answer/fail ratio statistics for that route step, trunk group or other particular routing leg features. Answer/fail statistics also may be set as universal limits based on advertised quality standards that are marketed by the calling card seller, or the QoS limits may include matrices of user-specific limits based on individual users' QoS criteria. The method continues to step 130 where the call data is updated. If any of the updated statistics determined at step 130 fall outside of the administrator provided QoS limits, an offending routing leg feature such as a particular carrier, or a particular trunk line, route step, or other route-specific feature that is determined to have caused the below-standard service, may be removed from the active list of route options stored in the routing database. The routing leg feature may then be added back to the active list according to the procedures described above concerning step 135. Finally, the method 100 again proceeds to step 140 and waits for the next call.

Those skilled in the art will readily recognize that the quality control sub-process defined by steps 125 and subsequent can be rearranged or changed significantly to adapt to various other empirical, real-time statistics concerning call quality that may become available to a system administrator. Those skilled in the art will also appreciate that the present invention is not limited to specific communications technologies, but is applicable to any system from which empirical, real-time performance data can be recovered.

The above-described method 100 of the present invention therefore defines an improved method of least-cost telephone call routing. The present invention incorporates QoS considerations as well as cost considerations into call routing calculations based on empirical, real-time QoS data. The present invention is thus useful for any telephone service providers or manufacturers of equipment of telephone service providers. In particular, users who have a large number of carrier arrangements or who employ extensively VoIP network protocols may gain substantial benefits from the improved method. End users who place telephone calls using the method 100 of the present invention may be given a much greater range of service quality and cost options than previously possible.

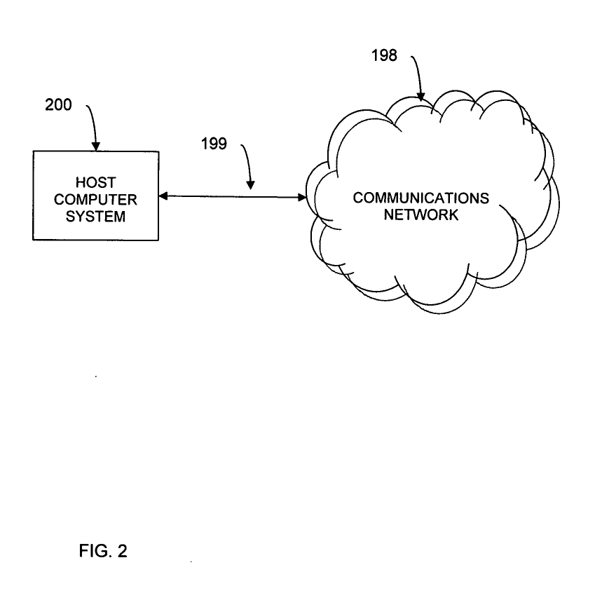

As represented in FIG. 2, the present invention comprises a host computer system 200 that implements the method described above which is operatively connected physically by various connecting mechanisms 199, such as wire, cable, or fiber optics, to various communications networks 198, such as the internet, virtual private networks (VPNs), PSTNs, satellite, and cellular wireless systems. Various communication technologies can be used to transmit the traffic across the networks, using various standards, including packet networks such as VoIP, voice over frame relay (VoFR), voice over asynchronous transfer mode (VoATM), and time division multiplexing (TDM) phone service including ISDN, DSL, Signaling System 7 (SS7), channel associated signaling (CAS), Common Control Switching Arrangement (CCSA). T1, and E1 and even analog technologies such as POTS. The host computer system 200 is operatively connected to a routing database that contains QoS criteria and cost criteria.

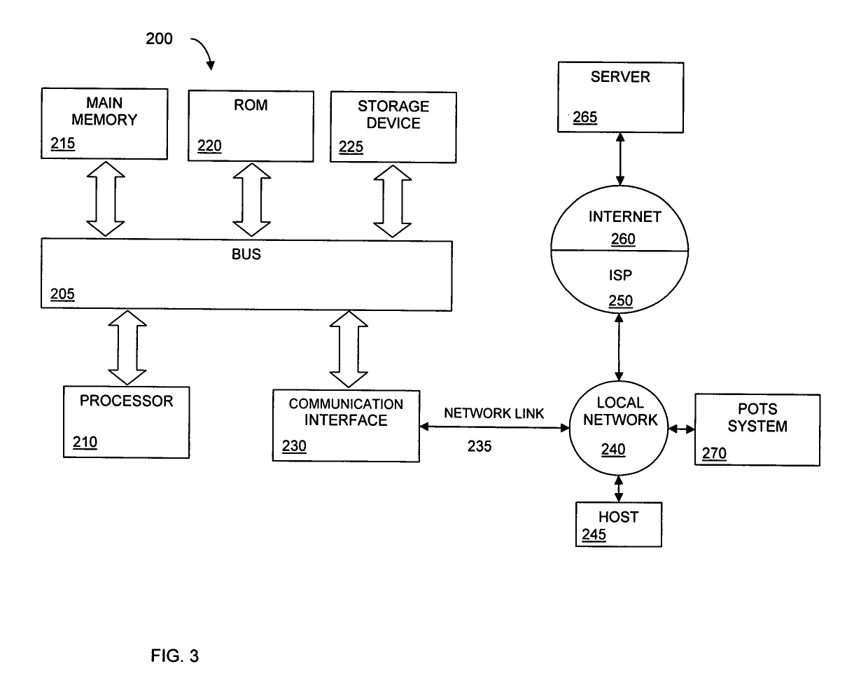

Referring to FIG. 3, there is a block diagram that illustrates the host computer system 200 through which one embodiment of the present invention may be implemented. As is known in the art, host computer systems make take on many configurations of hardware and software. FIG. 3 shows one embodiment of the host computer system 200 of the present invention, which includes a bus 205 or other communication mechanism for communicating information, and a processor 210 coupled with the bus 205 for processing information. The computer system 200 also includes a main memory 215, such as a random access memory (RAM) or other dynamic storage device, coupled to the bus 205 for storing information and instructions to be executed by the processor 210. The main memory 215 also may be used for storing temporary variable or other intermediate information during execution of instructions to be executed by the processor 210. The computer system 200 further includes a read only memory (ROM) 220 or other static storage device coupled to the bus 205 for storing static information and instructions for the processor 210. A storage device 225, such as a magnetic disk, optical disk or flash memory, is provided and coupled to the bus 205 for storing information and instructions. For example, the storage device 225 may be used to store the routing database described above that includes QoS criteria and cost criteria that are assigned to users or categories of users, and the least-cost route statistics and empirical QoS data.

The method 100 is facilitated by the computer system 200 in response to the processor 210 executing one or more sequences of one or more instructions contained in the main memory 215. Such instructions may be read into the main memory 215 from another computer useable medium, such as the storage device 225. Execution of the sequences of instructions contained in the main memory 215 causes the processor 210 to perform the steps of the method 100 described above. One or more processors in a multi-processing arrangement may also be employed to execute the sequences of instructions contained in the main memory 215. In alternative embodiments, hard-wired circuitry may be used in place of or in combination with software instructions to implement the invention. Thus, embodiments of the invention are not limited to any specific combination of hardware circuitry and software.

The term “computer useable medium” as used herein refers to any medium that participates in providing instructions to the processor 210 for execution. Such a medium may take many forms, including, but not limited to, non-volatile media, volatile media, and transmission media. Non-volatile media include, for example, optical or magnetic disks, or flash memory such as in the storage device 225. Volatile media include dynamic memory, such as the main memory 215. Transmission media include coaxial cables, copper wire, and fiber optics, including wires that comprise the bus 205. Transmission media can also take the form of acoustic or light waves, such as those generated during radio frequency (RF) and infrared (IR) data communications. Common forms of computer useable media include, for example, flexible disks, hard disks, magnetic tape, and any other magnetic media, CD-ROMs, DVDs, any other optical media, a RAM, a PROM, an EPROM, a FLASHEPROM, any other memory chip or cartridge, a carrier wave, or any other medium from which a computer can read.

Various forms of computer useable media may be involved in carrying one or more sequences of one or more instructions to the processor 210 for execution. For example, the instructions may initially be stored on a remote computer. The remote computer can load the instructions into its dynamic memory and send the instructions over a telephone line using a modem. A modem local to the computer system 200 can receive the data on the telephone line and use an optical transmitter to convert the data to an optical signal. An optical detector coupled to the bus 205 can receive the data carried on the optical signal and place the data on the bus 205. The bus 204 carries the data to the main memory 215, from which the processor 210 retrieves and executes the instructions. The instructions received by the main memory 215 may optionally be stored on the storage device 225 either before or after execution by the processor 210.

The host computer system 200 also includes a communication interface 230 coupled to the bus 205. The communication interface 230 provides a two-way data communication coupling to a network link 235 that is connected to a local network 240. For example, communication interface 230 may be an ISDN card or a modem to provide a data communication connection to a corresponding type of telephone line. As another example, communication interface 230 may be a local area network (LAN) card to provide a data communication connection to a compatible LAN. Wireless links may also be implemented. In any such implementation, the communication interface 230 sends and receives electrical, electromagnetic, or optical signals that carry digital data streams representing various types of information.

The local network 240 can also send messages and receive data, including program codes, through the network(s), network links 235, and communications interface 230. For example, if the host computer system 200 is operatively connected to the internet 260, a server 265 can transmit a requested code for a telephone call through the internet 260, an internet service provider (ISP) 250, the local network 240, and the communication interface 230. In accordance with the present invention, such a telephone call may be part of an implementation of the method 100 of communications routing described above. Alternatively, such a telephone call may be monitored directly through an operative connection of the local network 240 to the POTS system 270.

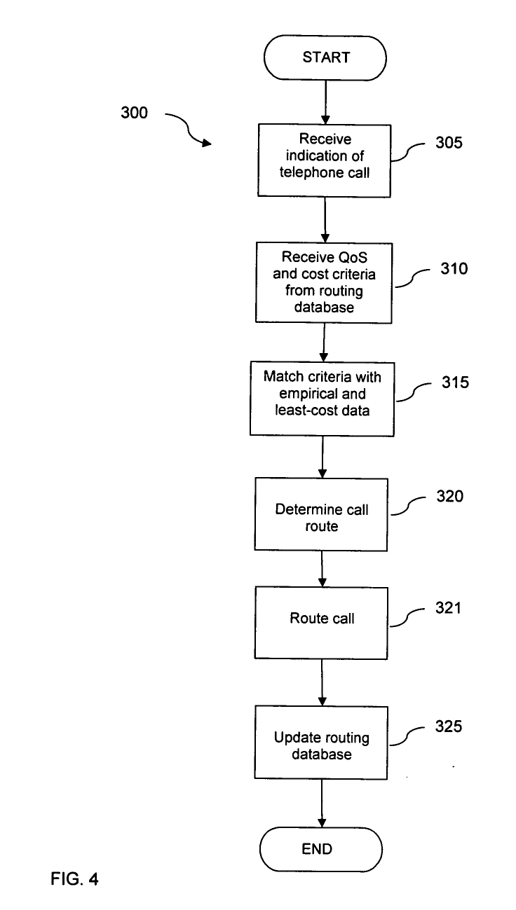

In summary, referring to FIG. 4, there is a flow diagram illustrating a general method 300 for communications routing according to an embodiment of the present invention. First, at step 305, a host computer system 200 receives an indication that a user has placed a telephone call. Next, at step 310, both QoS criteria and cost criteria are received from a routing database operatively connected to the host computer system 200. Cost criteria may include the cost per minute (basic cost), cost at a specific time of day, and cost at a given volume of traffic. At step 315, the QoS criteria and cost criteria are matched with empirical QoS data and least-cost routing data, respectively. The QoS criteria and cost criteria can be associated with a specific user or with a particular category of user. At step 320 a call route is determined based on the matched QoS criteria and cost criteria with empirical QoS data and least-cost routing data, respectively, and the call is routed at step 321. Once the call has ended—either with success or failure—the routing database is updated at step 325 with QoS parameters. The step 325 of updating the routing database may include all of the steps subsequent to step 125 described above with reference to the method 100.

While there has been illustrated and described what is at present considered to be the preferred embodiment of the present invention, it will be understood by those skilled in the art that various changes and modifications may be made and equivalents may be substituted for elements thereof without departing from the true scope of the invention. Therefore, it is intended that this invention not be limited to the particular embodiment disclosed, but that the invention will include all embodiments falling within the scope of the appended claims.

1. A method of communications routing that uses Quality of Service (QoS) data and least-cost statistics comprising:
receiving at a host computer system an indication that a user has placed a telephone call;
receiving at the host computer system from a routing database operatively connected to the host computer system QoS criteria and cost criteria;
matching the QoS criteria and cost criteria with empirical QoS data and least-cost routing data, respectively;
determining a call route based on the matched QoS criteria and cost criteria with empirical QoS data and least-cost routing data, respectively;
routing the call; and
updating the routing database with QoS data.

2. The method of claim 1 wherein the QoS criteria and cost criteria are associated with a specific user or with a particular category of user.

3. The method of claim 1 wherein updating the routing database is performed during a quality control sub-process in real time after the call is completed.

4. The method of claim 1 wherein updating the routing database comprises averaging the QoS data of the placed telephone call with overall average QoS data for a particular route step, trunk group, or other particular routing leg feature.

5. The method of claim 1 wherein updating the routing database comprises averaging a call duration of the placed telephone call with overall average call duration data for a particular route step, trunk group, or other particular routing leg feature.

6. The method of claim 1 wherein updating the routing database comprises averaging an answer delay of the placed telephone call with overall average answer delay data for a particular route step, trunk group, or other particular routing leg feature.

7. The method of claim 1 wherein the QoS criteria comprise at least one of answer/fail ratio, answer delay, decibel loss, number of retries, number of packets with errors, percentage of packets with errors, number of packets that were discarded, percentage of packets that were discarded, number of packets lost, percentage of packets lost, number of packets retransmitted, percentage of packets retransmitted, average jitter, maximum jitter, average latency, and maximum latency.

8. The method of claim 1 wherein updating the routing database comprises removing a particular routing leg feature from an active list of route options.

9. The method of claim 8 wherein the particular routing leg feature is selected from the group consisting of carriers, trunk lines, and route steps.

10. The method of claim 8 wherein updating the routing database further comprises adding a removed routing leg feature back onto the active list of route options after a predetermined suspension interval.

11. A system for communications routing that uses Quality of Service (QoS) factors and least-cost data, the system comprising:
a computer useable medium and computer readable code embodied on the computer useable medium for causing an execution of a transaction initiated by a user, the computer readable code comprising:
computer readable program code devices configured to cause the system to effect the receiving at the system of an indication that a user has placed a telephone call;
computer readable program code devices configured to cause the system to effect the receiving at the system from a routing database operatively connected to the system QoS criteria and cost criteria;
computer readable program code devices configured to cause the system to effect the matching of the QoS criteria and cost criteria with empirical QoS data and least-cost routing data, respectively;
computer readable program code devices configured to cause the system to effect the determining of a call route based on the matched QoS criteria and cost criteria with empirical QoS data and least-cost routing data, respectively;
computer readable program code devices configured to cause the system to effect the routing of a call; and
computer readable program code devices configured to cause the system to effect the updating of the routing database with QoS data.

12. The system of claim 11 wherein the QoS criteria and cost criteria are associated with a specific user or with a particular category of user.

13. The system of claim 11 wherein the updating of the routing database is performed during a quality control sub-process in real time after the telephone call is completed.

14. The method of claim 11 wherein updating the routing database comprises averaging the QoS data of the placed telephone call with overall average QoS data for a particular route step, trunk group, or other particular routing leg feature.

15. The system of claim 11 wherein the updating of the routing database comprises averaging a call duration of the placed telephone call with overall average call duration data for a particular routing leg feature.

16. The system of claim 11 wherein the updating of the routing database comprises averaging an answer delay of the placed telephone call with overall average answer delay data for a particular routing leg feature.

17. The method of claim 11 wherein the QoS criteria comprise at least one of answer/fail ratio, answer delay, decibel loss, number of retries, number of packets with errors, percentage of packets with errors, number of packets that were discarded, percentage of packets that were discarded, number of packets lost, percentage of packets lost, number of packets retransmitted, percentage of packets retransmitted, average jitter, maximum jitter, average latency, and maximum latency.

18. The system of claim 11 wherein the updating of the routing database comprises removing a particular routing leg feature from an active list of route options.

19. The system of claim 11 wherein the particular routing leg feature is selected from the group consisting of carriers, trunk lines, and route steps.

20. The system of claim 11 wherein the updating of the routing database further comprises adding a removed routing leg feature back onto the active list of route options after a predetermined suspension interval.

21. A system of communications routing comprising:
a host computer system for receiving an indication that a user has placed a telephone call;
a routing database operatively connected to the host computer system for storing QoS criteria and cost criteria;
a transmission medium for transmitting QoS criteria and cost criteria to the host computer system from the routing database;
wherein the host computer system:
matches the QoS criteria and cost criteria with empirical QoS data and least-cost routing data, respectively;
determines a call route based on the matched QoS criteria and cost criteria with empirical QoS data and least-cost routing data, respectively; and
updates the routing database with QoS data.
